(19) United States
(12) Patent Application Publication
(10) Pub. No.: US 2008/0204110 A1
(43) Pub. Date: Aug. 28, 2008

(54) LEVEL SHIFT CIRCUIT

(75) Inventor: Hideki Ishida, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki (JP)

(21) Appl. No.: 12/035,608

(22) Filed: Feb. 22, 2008

(30) Foreign Application Priority Data
Feb. 23, 2007 (JP) 2007-043770

(51) Int. Cl. H03L 5/00

(52) U.S. Cl. 327/333

(57) ABSTRACT

A level shift circuit for converting a first signal level into a second signal level, includes a load circuit connected to the second power supply voltage, a first high voltage-resistant transistor in which a drain is connected to the load circuit, and a predetermined constant voltage is applied to a gate, a source voltage control circuit controls a voltage level of the source of the first high voltage-resistant transistor in accordance with an input signal at the first signal level, and has a second low voltage-resistant transistor, and an output terminal which is connected between the drain of the first high voltage-resistant transistor and the load circuit for outputting an output signal at the second signal level. A gate insulating film of the low voltage-resistant transistor has a voltage resistance lower than that of a gate insulating film of the high voltage-resistant transistor.

### TECHNICAL FIELD

The present invention relates to a level shift circuit for converting a signal level of a low voltage power supply circuit into a signal level of a high voltage power supply circuit, and more specifically, it relates to a level shift circuit capable of appropriately propagating a signal.

### BACKGROUND

An operation voltage of an integrated circuit structure (hereinafter referred to as an LSI) has been decreasing accompanied with the microfabrication of the MOS transistor as a recent trend. Generally, the microfabrication level of the MOS transistor is defined by a gate length. As the microfabrication proceeds, the gate length is reduced to decrease the thickness of the gate oxide film. As a result, the gate voltage resistance and the threshold voltage of the transistor are reduced. Accordingly, as the microfabrication of the transistor proceeds, it is required to reduce the power supply voltage of the circuit formed of the subject transistor. In other words, the power supply voltage is reduced accompanied with the microfabrication of the transistor, which decreases the potential level of the inner signal as well as the signal amplitude.

The use of the improved material for forming the gate oxide film to increase the dielectric constant to the high value has been proposed for the purpose of avoiding reduction in the thickness of the gate oxide film caused by the microfabrication. The threshold voltage and the gate voltage resistance are reduced by increasing the dielectric constant even if the thickness of the gate oxide film is set to the same as that of the generally employed film. As the thickness of the gate oxide film is reduced, the gate tunnel current is suppressed. The circuit with the aforementioned transistor reduces the power supply voltage, the potential level of the inner signal, and the signal amplitude.

Meanwhile, in the case where the microfabricated LSI is connected to the generally employed external circuit device, the voltage level of the input/output signal is required to be adjusted to the signal level of the external device. That is, the inner circuit is operated by the low voltage power supply, and the input/output circuit shifts the signal level between the low voltage power supply and the high voltage power supply.

For example, the USB and HDMI are adapted to the signal voltage level of 3.3 V. Meanwhile, the LSI through the microfabricated CMOS process is adapted to the signal voltage level of 1.0 V, for example.

The LSI having the microfabrication proceeded contains an input/output circuit area powered by the high voltage power supply of the external circuit device in addition to the inner circuit area powered by the low voltage power supply.

The Japanese Unexamined Patent Application Publication No. 9-148913 discloses a circuit which shifts the signal level of the low voltage power supply circuit to a signal level of a high voltage power supply circuit, in which the circuit serves to shift the signal level via the intermediate power supply voltage circuit in case of the large difference between the low power supply voltage and the high power supply voltage.

The level shift circuit disclosed in the Japanese Unexamined Patent Application Publication No. 9-148913 inputs complementary signals at the forward and reverse phases in the low voltage power supply to the gate of a pair of N channel transistors a the ground power supply in the high voltage power supply circuit. The signal with the level shifted is output from the connection point between the drain of the pair of the N channel transistors and the pair of P channel transistors at the high voltage power device. (Japanese Unexamined Patent Application Publication No. 9-148913)

### SUMMARY

According to a first aspect of the present invention, a level shift circuit for converting a first signal level of a low voltage power supply circuit to which a first power supply voltage is supplied into a second signal level of a high voltage power supply circuit to which a second power supply voltage is supplied, having the second power supply voltage with an absolute value larger than that of the first power supply voltage includes a load circuit connected to the second power supply voltage, a first high voltage-resistant transistor in which a drain is connected to the load circuit, and a predetermined constant voltage is applied to a gate, a source voltage control circuit which is connected between a reference power supply and a source of the first high voltage-resistant transistor, controls a voltage level of the source of the first high voltage-resistant transistor in accordance with an input signal at the first signal level, and has a second low voltage-resistant transistor, and an output terminal which is connected between the drain of the first high voltage-resistant transistor and the load circuit for outputting an output signal at the second signal level. A gate insulating film of the low voltage-resistant transistor has a voltage resistance lower than that of a gate insulating film of the high voltage-resistant transistor.

### BRIEF DESCRIPTION OF THE DRAWINGS

FIG. 1A is a view showing structures of a high voltage-resistant transistor and a low voltage-resistant transistor according to an embodiment.

FIG. 1B is a view showing structures of a high voltage-resistant transistor and a low voltage-resistant transistor according to an embodiment.

FIG. 2 is a view showing a structure of an LSI having a built-in level shift circuit according to the embodiment.

FIG. 3A is a view showing the structure of the level shift circuit disclosed in prior art.

FIG. 3B is a view showing the operation of the level shift circuit disclosed in prior art.

FIG. 4 is a view showing a level shift circuit according to the embodiment.

FIG. 5 is a view showing a specific level shift circuit according to the embodiment.

FIG. 6A is a view showing another example of a constant voltage generation circuit.

FIG. 6B is a view showing another example of a constant voltage generation circuit.

FIG. 6C is a view showing another example of a constant voltage generation circuit.

FIG. 7A is a view showing another example of the load circuit and the protection circuit.

FIG. 7B is a view showing another example of the load circuit and the protection circuit.

FIG. 7C is a view showing another example of the load circuit and the protection circuit.

FIG. 8 is a view showing a level shift circuit having another protection circuit.

FIG. 9 is a view showing a level shift circuit as a modified example of the level shift circuit shown in FIG. 5 formed by setting the voltage power supply negative, and reversing the P and N channels.

### DESCRIPTION OF THE PREFERRED EMBODIMENTS

In the level shift circuit disclosed in Patent Document 1, the high voltage power supply circuit is formed of the high voltage-resistant transistor with high threshold voltage. If the signal level of the low voltage power supply circuit becomes too low, the low signal level does not match at the high threshold value of the high voltage resistant transistor. The transistor with the high voltage power supply circuit cannot be appropriately driven at the low signal level. As a result, the operation speed of the high voltage power supply circuit becomes low, and at worst, the signal cannot be propagated.

Accordingly, the object of the present invention is to provide a level shift circuit capable of propagating the signal by appropriately shifting the signal level to the one of the high voltage power supply circuit in spite of the signal level of the low voltage power supply circuit in the state where the microfabrication has been proceeded.

An embodiment will be described referring to the drawings. It is to be understood that the scope of the present invention is not limited to the embodiment to be described below, but contains the matters described in the claims and equivalents thereto.

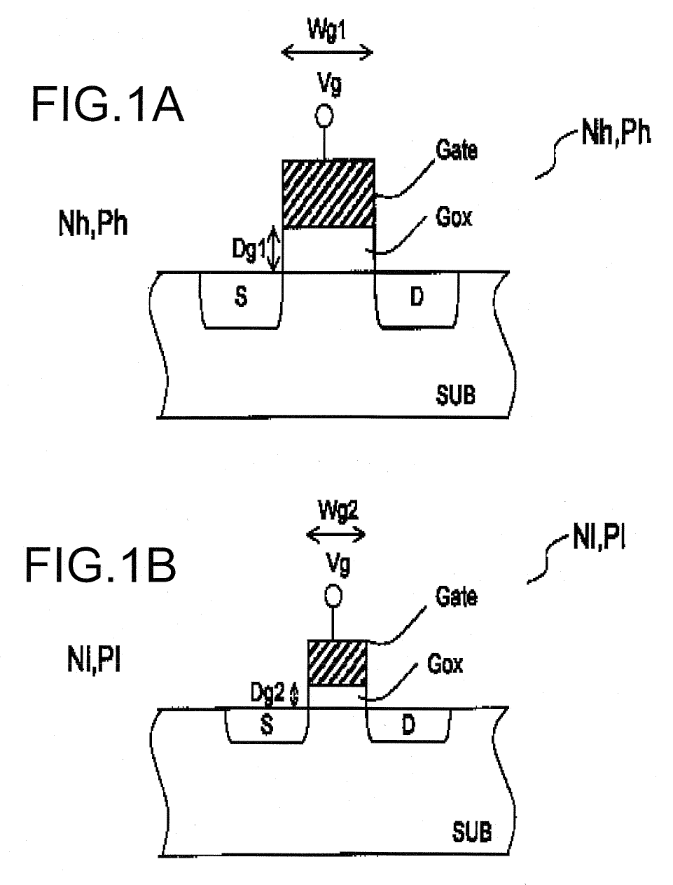

FIG. 1 shows structures of a high voltage-resistant transistor and a low voltage-resistant transistor. Each of the high voltage-resistant transistors Nh, Ph shown in FIG. 1A includes a source area S, a drain area D, a gate insulating film Gox formed therebetween, and a gate electrode Gate, which are formed on a surface of a semiconductor substrate SUB having the gate width of Wg1 and the gate insulating film thickness of Dg1. The Nh denotes an N channel MOS transistor, and Ph denotes a P channel MOS transistor.

Each of the low voltage-resistant transistors NI, PI shown in FIG. 1B includes a source area S, a drain area D which are formed on the surface of the semiconductor substrate SUB, a gate insulating film Gox and a gate electrode Gate formed therebetween. Each size of the low voltage-resistant transistors Nl, Pl is smaller than that of the high voltage resistant transistors Nh, Ph. Both the gate width Wg2 and the gate insulating film thickness Dg2 are smaller than the gate width Wg1 and the gate insulating film thickness Dg1, respectively.

The gate insulating film of the low voltage-resistant transistor has the voltage resistance lower than that of the high voltage-resistant transistor.

As another example of the low voltage-resistant transistor, the material for forming the gate insulating film is improved to increase the dielectric constant. The high dielectric constant prevents the reduction of the gate insulating film thickness to suppress the gate tunnel current. The high dielectric constant increases the field density exerted to the gate insulating film such that the voltage resistance is lowered under the high stress in spite of the gate insulating film which is not so thin. The voltage resistance and the threshold voltage of the low voltage-resistant transistor having the gate insulating film with the high dielectric constant become lower than those of the high voltage-resistant transistor having the gate insulating film with the low dielectric constant.

In the MOS process at relatively a slower pace, the integrated circuit using the high voltage-resistant transistors Nh, Ph is formed. Meanwhile, in the MOS process at relatively a high pace, the integrated circuit using the low voltage-resistant transistors NI, PI is formed.

The threshold voltages of the high voltage-resistant transistors Nh, Ph are higher than those of the low voltage-resistant transistors Nl, Pl for the structural reason. The power supply voltage of the integrated circuit using the high voltage-resistant transistors Nh, Ph is at a high potential corresponding to the high threshold voltage. Meanwhile, the power supply voltage of the integrated circuit using the low voltage-resistant transistors Nl, Pl is at the potential lower than that of the integrated circuit of the high voltage-resistant transistors in accordance with the low threshold voltage and the microfabricated transistor size.

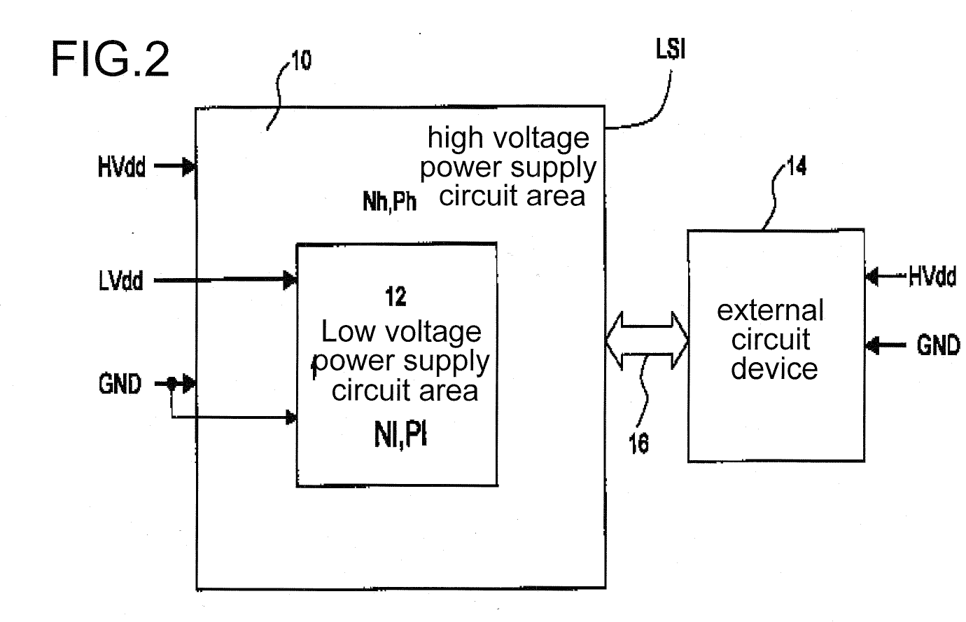

FIG. 2 is a view showing a structure of an LSI with a built-in level shift circuit according to the embodiment. The integrated circuit LSI in the progress of microfabrication includes a low voltage power supply circuit area 12 formed of the low voltage-resistant transistors Nl, Pl, and a high voltage power supply circuit area 10 formed of the high voltage-resistant transistors Nh, Ph, which are shown in FIG. 1. A low voltage power supply LVdd and the ground power supply GND are externally supplied to the low voltage power supply circuit area 12. A high voltage power supply HVdd and the ground power supply GND are externally supplied to the high voltage power supply circuit area.

The low voltage power supply circuit area 12 includes the integrated circuit formed of the microfabricated low voltage-resistant transistors Nl, P1. The integrated circuit is connected to the low voltage power supply LVdd and the ground power supply GND such that the signal level becomes low. Meanwhile, the high voltage power supply circuit area 10 includes the integrated circuit formed of the high voltage-resistant transistors Nh, Ph at the progress pace of the microfabrication lower than that in the case of the low voltage-resistant transistor. The integrated circuit is connected to the high voltage power supply HVdd and the ground power supply GND. A level conversion circuit for converting the low signal level corresponding to the low voltage power supply circuit area 12 into the high signal level corresponding to the high voltage power source HVdd in the high voltage power supply circuit area 10. Another level conversion circuit may be provided for performing the inverse signal conversion.

The output signal of the low voltage power supply circuit is converted into the higher signal level through the level conversion circuit within the high voltage power supply circuit, and supplied to an external circuit device 14 via a signal line 16. The output signal from the external circuit device 14 is supplied to the integrated circuit device LSI via the signal line 16. The external circuit device 14 receives the external supply of the high voltage power supply HVdd and the ground power supply GND to form the high voltage power supply circuit formed of the high voltage-resistant transistor. The signal level on the signal line 16 is high corresponding to the high voltage power supply HVdd.

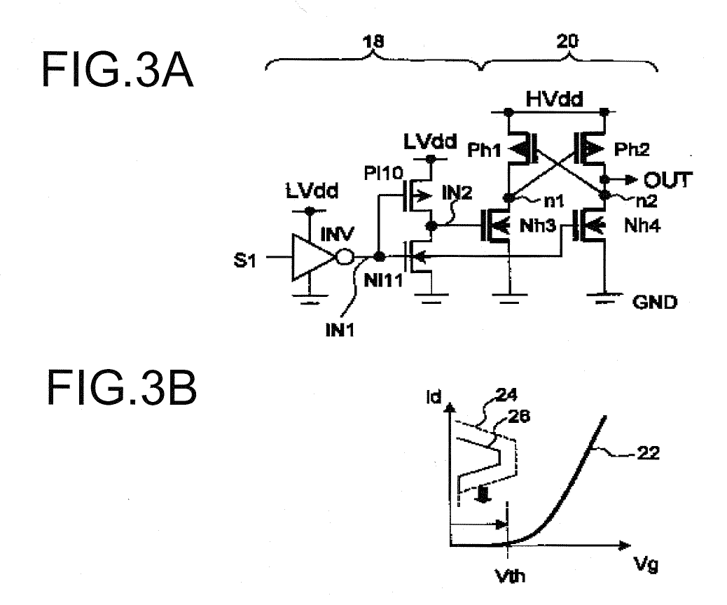

FIG. 3 is a view showing the structure and operation of the level shift circuit disclosed in Patent Document 1. The circuit diagram shown in FIG. 3A represents a low voltage power supply circuit 18, and a level conversion circuit 20 for converting the low level signals IN1, IN2 of the low voltage power supply circuit 18 into the high level signal OUT.

In the drawing, the high voltage-resistant transistors are designated with the codes of Ph and Nh, and the low voltage-resistant transistors are designated with the codes of Pl and Nl, respectively. The P channel transistor and the N channel transistor are designated with the codes of P and N, respectively. The positive low voltage power supply LVdd is used as the power supply voltage for the low voltage power supply circuit 18 in reference to the ground potential GND. The positive high voltage power supply HVdd is used as the power voltage for the level shift circuit 20.

In the low voltage power supply circuit 18, an inverter INV connected to the low voltage power supply LVdd and the ground GND inverts the inner signal S1 to output the first input signal IN1. The inverter formed of the low voltage-resistant transistors Pl10 and Nl11 connected to the low voltage power supply LVdd and the ground GND inverts the first input signal IN1 to output the second input signal IN2. The first and the second input signals IN1 and IN2 are low level signals each having H level of the low voltage power supply LVdd and the L level of the ground GND, respectively.

In the level conversion circuit 20, the high voltage-resistant P channel transistors Ph1, Ph2 and the N channel transistors Nh3, Nh4 are tandemly connected between the high voltage power supply HVdd and the ground GND, respectively. Gates of the transistors Ph1 and Ph2 are cross coupled with drains n1 and n2, respectively. The node n2 is connected to the output terminal OUT. The output terminal OUT outputs the high level signal having the H level of the high voltage power supply HVdd and the L level of the ground GND. Another output terminal may be connected to the node n1. In such a case, the high level complementary signal at the reverse phase is output.

If the inner signal S1 is at the L level, the first input signal IN1 is set to H level (Lvdd), the second input signal IN2 is set to L level (GND), the transistor Nh3 is turned OFF, the transistor Nh4 is turned ON, the node n1 is set to H level (HVdd), the node n2 is set to L level (GND), and the output OUT is set to L level. Meanwhile, if the inner signal S1 is at the H level, the first input signal IN1 is set to L level (GND), the second input signal IN2 is set to H level (LVdd), the transistor Nh3 is set to ON, the transistor NH 4 is set to OFF, the node n1 is set to L level (GND), the node n2 is set to H level (HVdd), and the output OUT is set to H level. As described above, the input signals IN1 and IN2 at the low level are level converted into the output OUT as the high level signal.

FIG. 3B shows gate voltage-drain current (Vg-Id) characteristic 22 of the high voltage-resistant N channel transistors Nh3, Nh4, and the input signals IN1, IN2. As the input signals IN1 and IN2 are input to the gates of the N channel transistors Nh3 and Nh4 having the source connected to the ground power supply GND, each signal waveform of the input signals IN1 and IN2 shows the one of the gate potential of the transistors Nh3 and Nh4.

As the H level of the input signal 24 indicated by the dashed line is high enough to exceed the threshold voltage Vd of the high voltage-resistant transistors Nh3 and Nh4, the transistors Nh3 and Nh4 may be sufficiently driven in response to the input signals IN1 and IN2 at the H level. This makes it possible to operate the aforementioned level inverter circuit.

When the voltage resistance of the transistor in the low voltage power supply circuit 18 is reduced accompanied with the microfabrication of the transistor to further reduce the level of the low voltage power supply LVdd, the H level of the input signal 24 is brought to be close to the threshold voltage Vth of the high voltage-resistant transistors Nh3 and Nh4. The transistors Nh3 and Nh4 may not be sufficiently driven by the input signal 24 at H level, thus failing to drive the nodes n1 and n2 to the L level. When the H level of the input signal 26 as indicated by the solid line becomes lower than the threshold voltage Vth of the transistors Nh3 and Nh4, the transistors Nh3 and Nh4 cannot be conducted, thus failing to normally operating the level shift circuit 20.

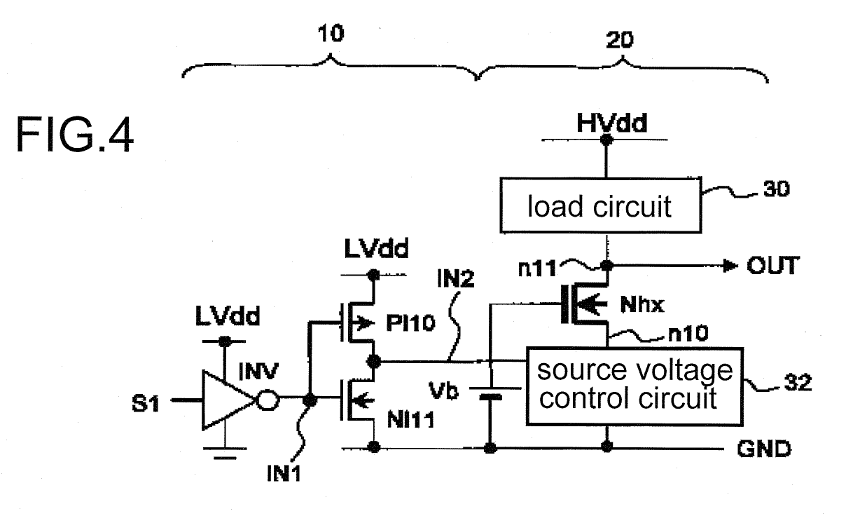

FIG. 4 is a view showing a level shift circuit according to the embodiment. A low voltage power supply circuit 10 shown in the drawing is the same as the one shown in FIG. 3. A level shift circuit 20 as the high voltage power supply circuit converts the input signal IN2 output from the inverter formed of the low voltage-resistant transistors Pl10, Nl11 into the high level signal OUT with the high voltage power supply HVdd at H level and the ground power supply GND at L level.

The level shift circuit 20 includes a load circuit 30 connected to the high voltage power supply HVdd, an N channel high voltage-resistant transistor Nhx having the gate connected to the constant voltage Vb and having the drain n11 connected to the load circuit, a source voltage control circuit 32 for controlling the voltage of the source n10 of the high voltage-resistant transistor Nhx in accordance with the input signal IN2. The source voltage control circuit 32 is formed of the low voltage-resistant transistor sufficiently driven by the input signal IN2 at the low level. The drain nil of the high voltage-resistant transistor Nhx is connected to the output terminal OUT.

The brief explanation with respect to the operation will be described. When the input signal IN2 is at the H level, the source voltage control circuit 32 lowers the potential of the source n10 of the high voltage-resistant transistor Nhx such that the level at the gate-source of the high voltage-resistant transistor Nhx is brought to be sufficiently higher level than the threshold voltage. The high voltage-resistant transistor Nhx is conducted to output the output signal at the L level to the output terminal OUT. Meanwhile, when the input signal IN2 is at the L level, the source voltage control circuit 32 fails to lower the potential of the source n10 of the high voltage-resistant transistor Nhx. As a result, the gate voltage of the source n10 of the high voltage-resistant transistor Nhx rises up from the gate voltage Vb to the level (Vb-Vth) lower than the threshold voltage. The high voltage-resistant transistor Nhx is brought into the non-conducted state to output the output signal at the H level to the output terminal OUT. The source voltage control circuit 32 positively drives the source n10 to become the H level such that the high voltage-resistant transistor Nhx is brought into the non-conducted state.

In the level shift circuit 20 shown in FIG. 4, the input signal IN2 as the low level signal is not input to the gate of the high voltage-resistant transistor Nhx. The source voltage control circuit 32 formed of the low voltage-resistant transistor which may be driven by the input signal IN2 controls the level of the source n10 of the high voltage-resistant transistor Nhx. Even if the microfabrication lowers the H level of the signal N2 in the low voltage power supply circuit due to microfabrication, this ensures that the high voltage-resistant transistor Nhx is brought into the conducted state, resulting in the appropriate level shift operation.

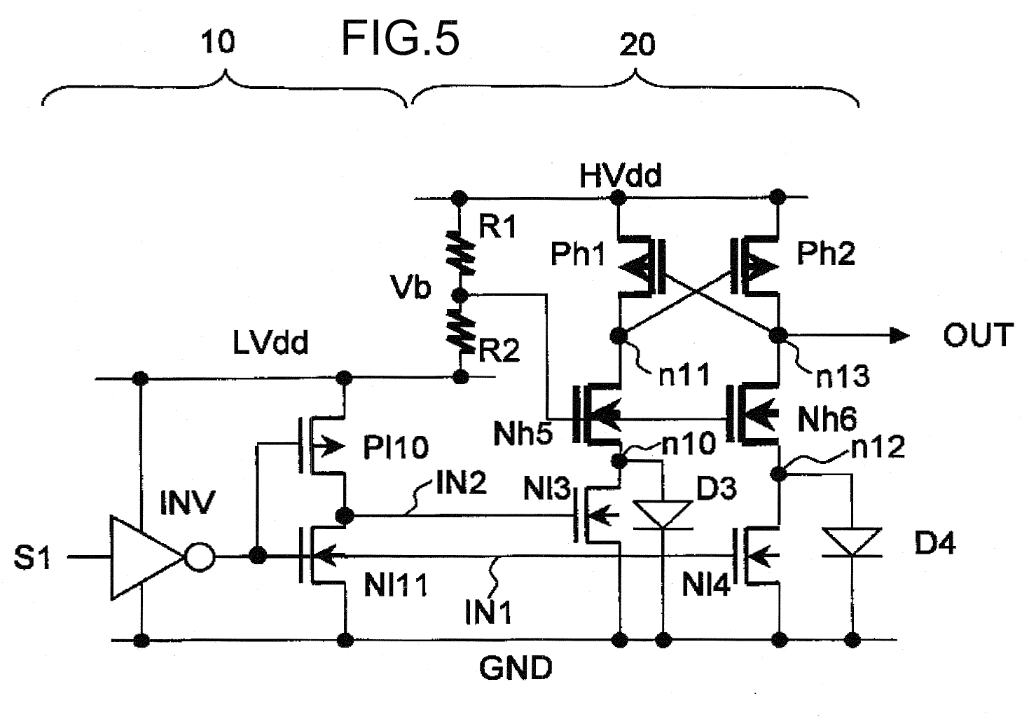

FIG. 5 is a view showing a specific level shift circuit according to the embodiment. The low voltage power supply circuit 10 is the same as those shown in FIGS. 3 and 4. The level shift circuit 20 is formed of a pair of circuits which operate in the reverse phase in response to the complementary signals IN1 and IN2 likewise the one shown in FIG. 3. That is, the level shift circuit 20 includes a first level shift circuit formed of a P channel high voltage-resistant transistor Ph1 of the load circuit connected to the high voltage power supply HVdd, an N channel high voltage-resistant transistor Nh5 having the gate connected to the constant voltage Vb, and an N channel low voltage-resistant transistor N13 having the gate receiving the second input signal IN2, and a second level shift circuit formed of a P channel high voltage-resistant transistor Ph2 of the load circuit connected to the high voltage power source HVdd, an N channel high voltage-resistant transistor Nh6 having the gate connected to the constant voltage Vb, and an N channel low voltage-resistant transistor N14 having the gate receiving the first input signal IN1. The low voltage-resistant transistors N13 and N14 form the source voltage control circuit 32.

The N channel low voltage-resistant transistors N13 and N14 have the source connected to the ground GND, and the gate receiving the input signals IN2 and IN1 as the low level signals, and the drain connected to the sources n10 and n12 of the high voltage-resistant transistors Nh5 and Nh6. The low voltage-resistant transistors N14 and N13 may be switched to the conducted/non-conducted state depending on H level and L level of the input signals IN1 and IN2. The pair of P channel high voltage-resistant transistors Ph1 and Ph2 which form the load circuit have the gate and drain cross coupled.

The constant voltage Vb is generated by a constant voltage generator circuit formed of resistances R1 and R2 interposed between the high voltage power supply HVdd and the low voltage power supply LVdd. The low voltage-resistant transistors N14 and N13 are brought into the conducted state when the input signals IN1 and IN2 are at the H level (LVdd). When the sources n12 and n10 of the high voltage-resistant transistors Nh6 and Nh5 are lowered to the ground GND, the constant voltage Vb is higher than the constant voltage power supply LVdd. Accordingly, the gate-source of the high voltage-resistant transistors Nh6 and Nh5 receives application of the voltage higher than the voltave LVdd. The high voltage-resistant transistors Nh6 and Nh5 are sufficiently brought into the conducted state compared with the level shift circuit shown in FIG. 3, thus capable of lowering the nodes n13 and n11. As those nodes n13 and n11 are sufficiently lowered, one of the high voltage-resistant transistors Ph1 and Ph2 for forming the load circuit is sufficiently brought into the conducted state, and lowering the level of the corresponding node either n11 or n13 to the level of the high voltage power supply HVdd.

The operation of the level shift circuit shown in FIG. 5 will be described. In the case where the inner signal S1 is at the L level, the level of the first input signal IN1 becomes H (LVdd), and the level of the second input signal becomes L (GND). Then the low voltage-resistant transistors N14 and N13 are brought into the conducted and non-conducted states, respectively, the node n12 is lowered to the ground GND, and the node n10 is raised. As the node n12 is lowered to the ground, the voltage is applied to the gate-source of the high voltage-resistant transistor Nh6, which is equal to or higher than the threshold voltage such that the transistor Nh6 is brought into the conducted state, and the node n13 is lowered. Meanwhile, the node n10 rises up to the high voltage power supply HVdd depending on the conducted state of the high voltage-resistant transistors Ph1 and Nh5 until it reaches the level lower by the threshold voltage of the transistor Nh5 from the constant voltage Vb, that is, Vb-Vth. The high voltage-resistant transistor Nh5 is brought into the non-conducted state. The node n10 is raised to the high voltage power supply HVdd to bring the high voltage-resistant transistor Ph2 into the non-conducted state. As a result, the node n13 and the output signal OUT may be sufficiently lowered to the ground level.

Conversely, in the case where the inner signal S1 is at the H level, the operation is performed in reverse to the aforementioned operation. That is, the level of the first input signal IN1 becomes L, and the low voltage-resistant transistor N14 is turned OFF. When the level of the second input signal IN2 becomes H (LVdd), the low voltage-resistant transistor N13 is turned ON. The node n10 is lowered to the ground level, and the voltage at the gate-source of the high voltage-resistant transistor Nh5 sufficiently exceeds the threshold voltage. As a result, the high voltage-resistant transistor Nh5 is brought into the conducted state, and the node n11 is lowered to the ground side. Then the high voltage-resistant transistor Ph2 is brought into the conducted state, and each level of the node n13 and the output signal OUT becomes H (HVdd).

As the low voltage-resistant transistors N13 and N14 are provided as the source voltage control circuit 32, the input signals IN2 and IN1 at the H level as the low level signals in the low voltage power supply circuit 10 sufficiently bring the low voltage-resistant transistors N13 and N14 into the conducted state, thus lowering the source potential of the high voltage-resistant transistors Nh5 and Nh6 to the ground. As the fixed voltage Vb higher than the low voltage power supply LVdd is applied to the gate of the high voltage-resistant transistors Nh5 and Nh6, the high voltage-resistant transistors Nh5 and Nh6 may be sufficiently brought into the conducted state owing to Vb>>Vth. Even if the node n11 or n13 is at the H level, and the P channel high voltage-resistant transistors Ph1 and Ph2 as the corresponding load circuit are in the conducted state, the high voltage-resistant transistors Nh5 and Nh6 may be sufficiently driven to lower the nodes n11 and n13. Then the opposite P channel transistors Ph1 and Ph2 are brought to be in the conducted state to bring the P channel high voltage-resistant transistors Ph1 and Ph2 as the corresponding load circuit into the non-conducted.

This ensures to propagate the low level signals IN1 and IN2 of the low voltage power supply circuit 10 to the node n13 and the output terminal OUT as high level signals of the high voltage power supply circuit 20.

Referring to FIG. 5, diodes D3 and D4 each formed of a junction diode as a protection circuit between the drains n10, n12 and the ground GND such that the voltage equal to or higher than the voltage-resistant voltage of the transistor is not applied to the drain-gate of the low voltage-resistant transistors N13 and N14. The diodes D3 and D4 each formed of the junction diode serve to clamp the nodes n10 and n12 at approximately the junction voltage (about 0.6 V) for preventing the voltage equal to or higher than the voltage-resistant voltage to the low voltage-resistant transistors N13 and N14.

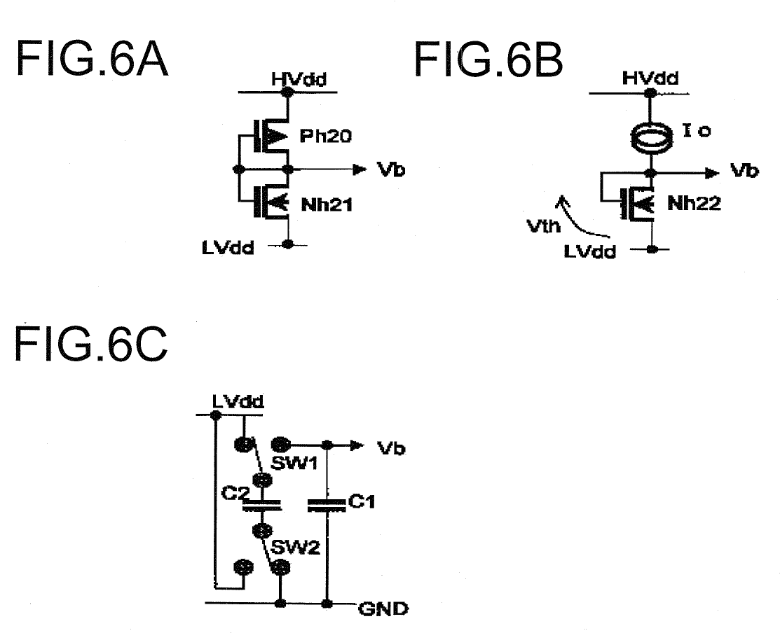

FIG. 6 shows another example of the constant voltage generation circuit. In the constant voltage generation circuit shown in FIG. 6A, a P channel high voltage-resistant transistor Ph20 and an N channel high voltage-resistant transistor Nh 21 which are diode connected are connected in series between the high voltage power supply HVdd and the low voltage power supply LVdd. The level of the constant voltage Vb is obtained by dividing the interspace between the high voltage power supply HVdd and the low voltage power supply LVdd in accordance with the impedance ratio in the conducted states of the transistors Ph20 and Nh21.

Referring to FIG. 6B, a constant current source Io and an N channel high voltage-resistant transistor Nh 22 are connected between the high voltage power supply HVdd and the low voltage power supply LVdd, and the respective connection points output the constant voltage Vb. In the circuit, the constant voltage Vb is controlled to the high level of the threshold voltage of the N channel transistor Nh21 from the low voltage power supply LVdd. When the threshold voltage of the N channel transistor rises up owing to variation in the process, the constant voltage Vb is increased. Even if the threshold voltage values of the high voltage-resistant transistors Nh5 and Nh6 of the N channel in the level shift circuit rise up, the transistors Nh5 and Nh6 may be sufficiently driven into the conducted state. The resultant constant voltage Vb copes with the fluctuation in the threshold voltage caused by the variation in the process.

Referring to FIG. 6C, the low voltage power supply LVdd is boosted by a charge pump circuit with the switched capacitor between the low voltage power supply LVdd and the ground GND to generate the constant voltage Vb. That is, two switches SW1 and SW2 are set as shown in the drawing to perform the electrical charge from the low voltage power supply LVdd to the capacitor C2. Thereafter, the switches SW1 and SW2 are switched to the state reverse to the one shown in the drawing such that the capacitors C1 and C2 are connected in series between the ground GND and the low voltage power supply LVdd. The charge in the capacitor C2 is fed to the capacitor C1 to boost the constant voltage Vb.

The constant voltage generation circuit boosts the low voltage power supply LVdd to generate the constant voltage Vb, which is decreased as the low voltage power supply LVdd decreases. Conversely, the constant voltage Vb is increased as the low voltage power supply LVdd increases. This makes it possible to generate the constant voltage which follows the change in the low voltage power supply LVdd.

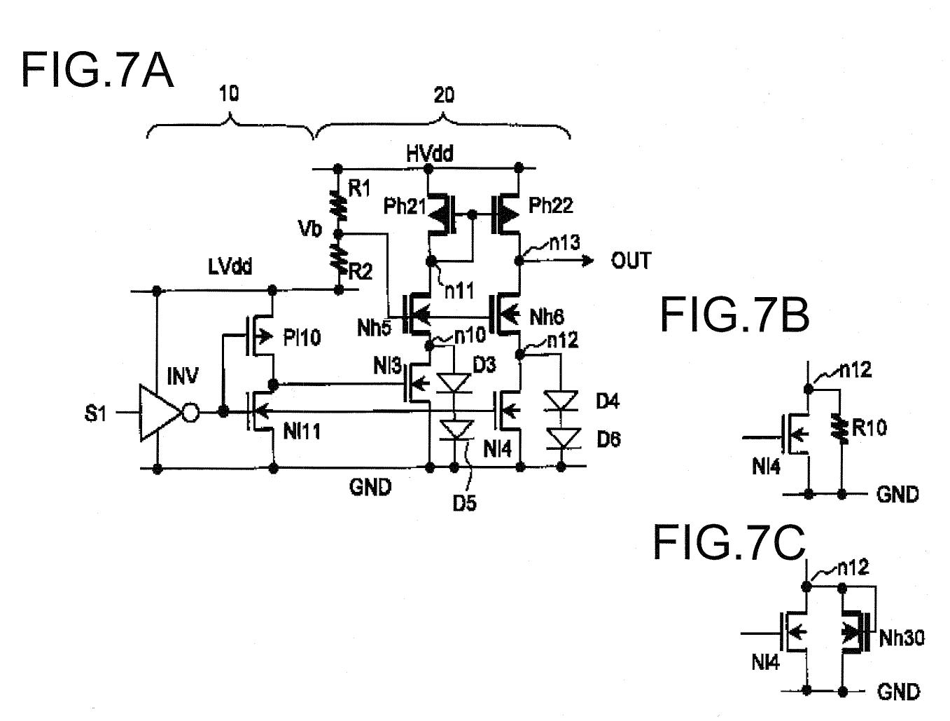

FIG. 7 shows another example of the load circuit and the protection circuit. Referring to FIG. 7A, the P channel high voltage-resistant transistors Ph21 and Ph22 connected to the gates are provided as the load circuit of the level shift circuit 20. The gate of the transistor Ph21 is connected to the drain (n11). Both the transistors form the current mirror circuit for applying the constant current at the current ratio in accordance with the transistor size.

Unlike the load circuit of the transistors Ph1 and Ph2 having the gate and the drain cross coupled as shown in FIG. 5, the aforementioned load circuit causes no latch upon the reversing operation. The output signal OUT greatly changes in response to the change in the current depending on the conducted/non-conducted state of the high voltage-resistant transistor Nh6, supplying the gain to the output signal OUT.

FIG. 7A shows a protection circuit of the low voltage-resistant transistor N13 having two diodes D3 and D5 connected in series, and a protection circuit of the low voltage-resistant transistor N14 having the diodes D4 and D6 connected in series. Sources n10 and n12 of the high voltage-resistant transistors Nh5 and Nh6 rise up to the Vb-Vth (Vth: threshold value) when the low voltage-resistant transistors N13 and N14 connected thereto are in an OFF state. If the Vb-Vth is kept lower than the resistant voltage of the low voltage-resistant transistors N13 and N14, the transistors N13 and N14 may be protected from the destruction. The protection circuits D3, D5 or D4, D6 may be provided just in case the high voltage is not applied to the nodes n10 and n12. It is preferable to make the forward voltage of the two diodes higher than the Vb-Vth. For example, in the case where the resistant voltage of the low voltage-resistant transistors N13, N14 is approximately 0.8 V, it is preferable to employ the diode with a single stage as the protection circuit as shown in FIG. 5. In the case where the resistant voltage is approximately 1.5 V, it is preferable to employ the diode with two stages as the protection circuit as shown in FIG. 7.

FIG. 7B shows another example of the protection circuit. In this example, a resistance R10 is provided between the node n12 as the drain of the low voltage-resistant transistor N14 and the ground GND.

FIG. 7C shows another example of the protection circuit. In this example, an N channel high voltage-resistant transistor Nh 30 is provided between the node n12 and the ground GND. In this case, it is preferable to make the threshold voltage of the transistor Nh20 higher than the aforementioned Vb-Vth.

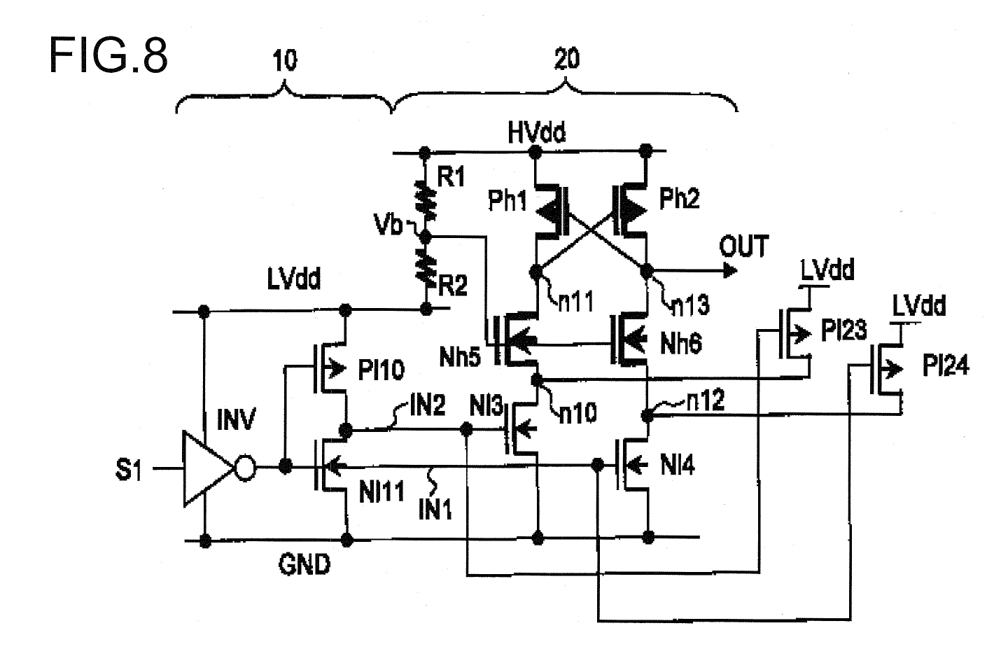

FIG. 8 is a view showing the level shift circuit with another protection circuit. Likewise the example shown in FIG. 5, the load circuit is formed of a pair of P channel high voltage-resistant transistors Ph1, Ph2 each having the gate and the drain cross coupled. The low voltage-resistant transistors N13 and N14 are connected to P channel low voltage-resistant transistors P123 and P124 having the gate connected to the input signals IN2 and IN1, and the source connected to the low voltage power source LVdd. The low voltage-resistant transistors P123 and P124 are brought into the conducted state when each level of the input signals IN2 and IN1 becomes L to raise the nodes n10 and n12 to the low voltage power supply LVdd. That is, the nodes n10 and n12 are clamped with the low voltage power supply LVdd. Accordingly, if the low voltage power supply LVdd is higher than the level Vb-Vth of the nodes n10 and n12 at which the high voltage-resistant transistors Nh5 and Nh6 are brought into the non-conducted state (Vb-Vth<LVdd), the operation for turning the high voltage-resistant transistors Nh5 and Nh6 OFF may be performed and the low voltage-resistant transistors N13 and N14 may be protected by the destruction.

From the different aspect, the protection circuit shown in FIG. 8 is structured by connecting the node n12 to the output of the inverter formed of the transistors N14 and P124 for inputting the input signal IN1, and connecting the node n10 to the output of the inverter formed of the transistors N13 and P123 for inputting the input signal IN2. That is, the inverter formed of the transistors N14 and P124 serves as a source voltage control circuit 32 for controlling the level of the source n12 in accordance with the input signal IN1. Likewise, the inverter formed of the transistors N13 and P123 serves as the source voltage control circuit 32 for controlling the level of the source n10 in accordance with the input signal IN2. The aforementioned inverters may be dynamically controlled to the ground GND level and the low voltage power supply LVdd level in accordance with the input signals In2 and IN1. The high voltage-resistant transistors Nh5 and Nh6 may be statically brought to be in the OFF state at the higher rate than the case as shown in FIG. 5. Only the low voltage power supply LVdd is applied to the low voltage-resistant transistors N13 and N14 so as to be protected.

The level shift circuits shown in FIGS. 5, 7 and 8 may be structured as the circuit for converting the low level signal in the first negative voltage power supply circuit with the absolute value smaller than that of the ground GND into the high signal level of the second negative voltage power supply circuit with the larger absolute value. In the aforementioned case, the P and N channels are reversed.

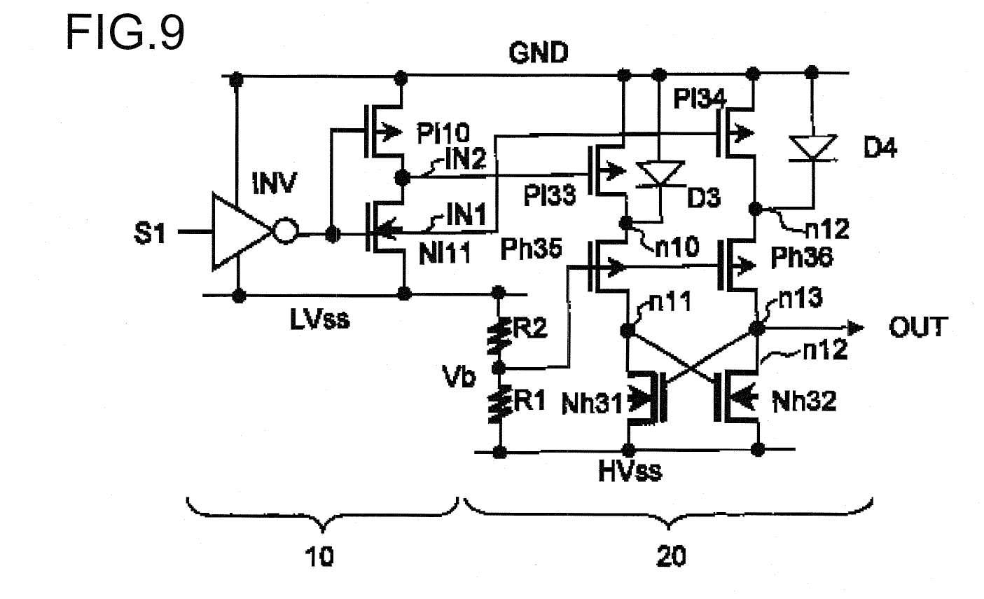

FIG. 9 is a view showing the level shift circuit with the negative voltage power supply, having the P channel and the N channel reversed. The absolute value of the low voltage power supply LVss with respect to the ground GND is smaller than the absolute value of the high voltage power supply HVss. The low voltage power supply circuit 10 has the same structure as that shown in FIG. 5.

In the level shift circuit 20, the P channel low voltage-resistant transistor P124 forms the source voltage control circuit, to which the first input signal IN1 is input to the gate. The N channel high voltage-resistant transistor Nh32 forms the load circuit connected to the p channel high voltage-resistant transistor Ph36. The output terminal OUT is connected to the aforementioned connection points. In another level shift circuit 20, the P channel low voltage-resistant transistor P123 having the second input signal IN2 input to the gate forms the source voltage control circuit. The N channel high voltage-resistant transistor Nh31 forms the load circuit connected to the P channel high voltage-resistant transistor Ph35. Then the high voltage-resistant transistors Nh31 and Nh32 in the load circuit have the gate and the drain cross coupled.

The operation of the level shift circuit shown in FIG. 9 is substantially the same as the operation shown in FIG. 5 except that the polarity is reversed. For example, if the inner signal S1 is at the H level, the level of the first input signal IN1 becomes L (LVss). Then the P channel low voltage-resistant transistor P134 is brought into the conducted state, and the node n12 is raised to the ground GDN. Accordingly, the P channel high voltage-resistant transistor Ph26 is brought into the conducted state to raise the node n13 to the ground. The N channel high voltage-resistant transistor Nh31 is brought into the conducted state to lower the node n11 to the L level (HVss). The high voltage-resistant transistor Nh32 is brought into the non-conducted state. As a result, the output signal OUT becomes H level (ground GND). Meanwhile, if the level of the inner signal S1 becomes L, the first input signal IN1 is set to the H level (GND). As the operation is performed reverse to the aforementioned to set the output signal OUT to the L level (HVss).

The level shift circuits shown in FIGS. 7 and 8 are allowed to employ the level shift circuit corresponding to the negative voltage power source LVss, and HVss likewise the circuit shown in FIG. 9.

The level shift circuit of the embodiment is structured to input the low level signal in the low voltage power supply circuit into the source voltage control circuit formed of the low voltage-resistant transistor such that the source level of the high voltage-resistant transistor of the constant voltage gate is controlled. Even if the low voltage power supply is lowered accompanied with the microfabrication, the level shift circuit may be normally operated.

What is claimed is:

1. A level shift circuit for converting a first signal level of a low voltage power supply circuit to which a first power supply voltage is supplied into a second signal level of a high voltage power supply circuit to which a second power supply voltage is supplied, the second power supply voltage having an absolute value larger than that of the first power supply voltage, the level shift circuit comprising:
a load circuit connected to the second power supply voltage;
a first high voltage-resistant transistor in which a drain is connected to the load circuit, and a predetermined constant voltage is applied to a gate;
a source voltage control circuit which is connected between a reference power supply and a source of the first high voltage-resistant transistor, controls a voltage level of the source of the first high voltage-resistant transistor in accordance with an input signal at the first signal level, and has a second low voltage-resistant transistor; and
an output terminal which is connected between the drain of the first high voltage-resistant transistor and the load circuit for outputting an output signal at the second signal level, wherein a gate insulating film of the low voltage-resistant transistor has a voltage resistance lower than that of a gate insulating film of the high voltage-resistant transistor.

2. The level shift circuit according to claim 1, wherein the second low voltage-resistant transistor of the source voltage control circuit has a first conductive type low voltage-resistant transistor in which a source is connected to the reference power supply, the input signal is supplied to a gate, and a drain is connected to the source of the first high voltage-resistant transistor.

3. The level shift circuit according to claim 2, wherein:
the first high voltage-resistant transistor is the first conductive type high voltage-resistant transistor; and
when the second low voltage-resistant transistor is switched to a conducted state in accordance with the input signal, the first high voltage-resistant transistor is brought into a conducted state for setting the output signal to a first level, and when the second low voltage-resistant transistor is switched to a non-conducted state in accordance with the input signal, the first high voltage-resistant transistor is brought into the non-conducted state for setting the output signal to a second level having an absolute value larger than that of the first level.

4. The level shift circuit according to claim 3, wherein the load circuit includes a second conductive type high voltage-resistant transistor in which a source is connected to the second power supply voltage, and a drain is connected to a drain of the first high voltage-resistant transistor.

5. The level shift circuit according to claim 3, which includes a clamp circuit for clamping the drain of the second low voltage-resistant transistor from the reference power supply to a predetermined level between the drain of the second low voltage-resistant register and the reference power supply.

6. The level shift circuit according to claim 1, wherein the second low voltage-resistant transistor of the source voltage control circuit includes a first conductive type low voltage-resistant transistor in which a source is connected to the reference power supply, the input signal is supplied to the gate, and the drain is connected to the source of the first high voltage-resistant transistor, and a second conductive type low voltage-resistant transistor in which a source is connected to the first power supply voltage, the input signal is supplied to the gate, and the drain is connected to the source of the first high voltage-resistant transistor.

7. The level shift circuit according to claim 1, which further includes a constant voltage circuit provided between the first power supply voltage and the second power supply voltage for outputting an intermediate voltage between the first and the second power supply voltages to the gate of the first high voltage-resistant transistor as the predetermined constant voltage.

8. The level shift circuit according to claim 1, which includes a charging pump circuit for outputting a boosted voltage obtained by boosting the first power supply voltage as the predetermined constant voltage so as to be output to the gate of the first high voltage-resistant transistor.

9. A level shift circuit for converting a first signal level of a low voltage power supply circuit to which a first power supply voltage is supplied into a second signal level of a high voltage power supply circuit to which a second power supply voltage is supplied, the second power supply voltage having an absolute value larger than that of the first power supply voltage which includes:
a pair of load circuits connected to the second power supply voltage;
first and second high voltage-resistant transistors connected to the pair of load circuits, being first conductive type, having each gate to which a predetermined constant voltage is applied;
third and fourth low voltage-resistant transistors in which a source is connected to a reference power supply, a drain is connected to each source of the first and the second high voltage-resistant transistors, and a pair of input signals each having opposite phase with the first signal level so as to be supplied to the respective gates, the third and fourth low voltage-resistant transistors being first conductive type; and
an output terminal connected between the pair of the load circuits and the first or the second high voltage-resistant transistors to output an output signal at the second signal level, wherein a gate insulating film of the low voltage-resistant transistor has the voltage resistance lower than that of the gate insulating film of the high voltage-resistant transistor.

10. The level shift circuit according to claim 9, wherein:
the pair of load circuits have a source connected to the second power supply voltage, and second conductive type fifth and sixth high voltage-resistant transistors each having the drain and the gate cross coupled; and
the drains of the fifth and the sixth high voltage-resistant transistors are connected to those of the first and the second high voltage-resistant transistor, and the drains of the first or the second high voltage-resistant transistors are connected to the output terminal.

11. The level shift circuit according to claim 9, wherein:
the pair of load circuits have the source connected to the second power supply voltage, and second conductive type fifth and sixth high voltage-resistant transistors have each gate commonly connected to one of the drains; and
the drains of the fifth and the sixth high voltage-resistant transistors are connected to those of the first and the second high voltage-resistant transistors, and the drain of the first or the second high voltage-resistant transistor is connected to the output terminal.

12. The level shift circuit according to claim 9, which further includes second conductive type seventh and eighth low voltage-resistant transistors in which a source is connected to a first power supply voltage, and a drain is connected to sources of the first and the second high voltage-resistant transistors, and a pair of input signals each having an opposite phase are supplied to the respective gates.

13. The level shift circuit according to claim 9, wherein the pair of the input signals each having an opposite phase are formed of input and output signals of an inverter including second conductive type ninth low voltage-resistant transistor, and a first conductive type tenth low voltage-resistant transistor interposed between the first power supply voltage and the reference voltage.
